(19) United States
(12) Patent Application Publication
(10) Pub. No.: US 2010/0321859 A1
(43) Pub. Date: Dec. 23, 2010

(54) Annular Capacitor with power conversion components arranged and attached in manners uniquely allowed by the ring shaped form factor

(75) Inventor: Terry Hosking, Barre, VT (US)

Correspondence Address: Terry Hosking;SBE Inc., 131 S. Main St., Barre, VT, 05641, US

(73) Assignee: SBElectronics Inc., Barre, VT (US)

(21) Appl. No.: 12/807,310

(22) Filed: Oct. 30, 2008

Related U.S. Application Data
(60) Provisional application No. 60/984,561, filed on Nov. 1, 2007.
(60) Provisional application No. 60/984,546, filed on Nov. 1, 2007.
(60) Provisional application No. 60/984,530, filed on Nov. 1, 2007.

(51) Int. Cl. H01G 4/32; H05K 7/00; H05K 7/20

(52) U.S. Cl. 361/301.5; 361/782; 361/712

(57) ABSTRACT

The formation of an assembled unit consisting of an annular capacitor [a wound, metallized dielectric capacitor in the shape of a closed path ring] with other power conversion components arranged and attached in manners uniquely allowed by the ring design will allow higher density converter designs [power/unit volume]. The resulting short connection paths between the capacitor element and the switching semiconductors also provide a very low inductance path that minimizes voltage spikes on the switching semiconductors as a result of turn-off di/dt. The capacitor serves as a short time current source and sink for the switching semiconductors. With the described configuration the RMS current seen by the capacitor can be made more volumetrically uniform enabling more uniform capacitor rise. The single capacitor configured as described also mitigates bus resonance problems often observed in prior art when multiple discrete capacitors are connected in parallel.

### CROSS-REFERENCE TO RELATED APPLICATIONS

This application claims the priority of U.S. Provisional Application Ser. Nos. 60/984,561, 60/984,546, and 60/984,530 filed Nov. 1, 2007 and entitled, respectively, “Annular capacitor with semiconductors around the perimeter to perform power conversion”, “Annular capacitor with semiconductor die or modules inside the hole for power conversion”, and “Annular capacitor with power conversion semiconductor electronics contained inside the center hole”, the subject matter of which are incorporated herein by reference. The invention herein follows from the same inventor's recent U.S. Pat. No. 7,289,311, “Power ring pulse capacitor” issued 30 Oct. 2007.

### BACKGROUND OF THE INVENTION

1. Field of Invention

The invention relates to an annular form factor capacitor when used as the DC link capacitor in power conversion electronics. More specifically it relates to the arrangement options for placement of power switching devices around or inside said capacitor which result in the lowest capacitor internal temperature rise for a given capacitor current. Lower internal temperature will result in reliability improvement. Another way of stating the advantages of these configuration options will be the higher current allowed through the capacitor for a given temperature rise. These arrangement options also allow lower inductance connections between the DC link capacitor and the semiconductor switches than typical prior art.

2. Description of the Prior Art

In broadly applied power conversion technology for conversion of DC voltages, or inversion of DC to AC, the typical circuit arrangement makes use of a capacitor located as close as practical to the switching semiconductor devices. This capacitor is used to reduce the impedance of the DC source as seen by the switching devices. This capacitor is required for several reasons.
1) It supplies current to the conversion/inversion switches at the switch frequency used. This removes the otherwise high frequency current from the DC source, where it is often detrimental to the lifetime and reliability of this source.
2) It removes most of the “noise” caused by the switching action and helps contain it within the power conversion/inversion enclosure.
3) Its low inductance to the switches reduces the voltage rise at the switches during the switch turn-off time, which is a major problem for inverter/converter designers.

This capacitor also stores energy so that short-term interruption of the DC source will not interrupt the output, but that function is not relevant to the proposed invention.

In the known art of power conversion/inversion a capacitor used in this application is known as the “DC link capacitor”. This capacitor is usually sized based on the magnitude of AC current at the switching frequency that must be supplied by the capacitor to the switches, and by the maximum AC current that is acceptable to the application DC source. For large power conversion systems, the capacitor winding machines commercially available as of 15 Oct. 08 are unable to wind a single capacitor element large enough to meet the DC link capacitor need. Suitable capacitors are made by interconnecting 2 or more capacitor windings to obtain the desired voltage and AC current carrying requirements. This can be done by a capacitor manufacturer, with the completed assembly enclosed within a metal or plastic container with at least one terminal pair for connection to the power conversion system. The DC Link capacitor can also be a “bank” of several suitably configured discrete capacitors.

For both of these implementations [internally connected capacitor windings, or externally connected capacitors] it is nearly impossible to ensure that each capacitance element will carry the same current because that would imply equal impedance connections from the switch semiconductors to each capacitor element. The capacitor windings nearest [thus having lowest impedance to] the switches will carry disproportionate current with resulting disproportionate heating. The closest capacitors to the switch semiconductors will capture the largest share of the resulting AC current.

The prior art performance limitation for an assembled DC link capacitor implementation is that the temperature rise in the capacitor element carrying the most current will define the current carrying capability of the entire capacitor; it is difficult to minimize the inductance between the capacitor elements and the switch semiconductors.

For the user assembled “capacitor bank” DC link capacitor, the same problem exists, the individual capacitors in the bank located closest to the switch semiconductors will carry more than their share of the current. This is because the closest capacitors will have the shortest distance to the current source and thus the lowest impedance in the circuit.

The long-term reliability of a capacitor is a function of the hottest spot in the capacitor under the current load conditions. The weaknesses and eventual failure will occur in this area. Thus, the long-term reliability of the capacitor will be a function of the hottest spot within the capacitor.

### BRIEF SUMMARY OF THE INVENTION

In the present invention, the DC Link capacitor is an annular form factor [ring shaped] capacitor. In the invention, the power semiconductor switches are arranged in a way to more evenly distribute the switched current around the area of the capacitor shape. By more evenly distributing the current around the annular shape, the current density at any one connection point is reduced by the number of equally arranged connection points attached to the capacitor. This reduced current density at any one connection point directly reduces the non uniformity of current density within the capacitor, with the result of more uniform losses and reduced temperature rise at any point for a given total capacitor current.

One advantage of the invention is low heat dissipation for a given switching current.

Another advantage of the invention is the increased long term reliability of the DC Link capacitor for any given capacitor current; the capacitor reliability is a function of hot spot temperature: lowering the temperature by 10 C will, on average, improve the reliability by a factor of 2.

Another advantage of the present invention is that it has a very low Effective Series Inductance [ESL]. The short distances from capacitor to switches result in low inductance, which reduces voltage overshoot seen by the switch devices when they turn off.

Another related advantage offered by the low ESL is the possible elimination of the need for additional snubber capacitors across the terminals of the power semiconductor switches.

Another advantage of the present invention is that it has a very low Effective Series Resistance [ESR]. The more uniform current density within the capacitor results in less heating, which is reflected as lower ESR.

Another advantage is that a simplified connection bus structure is possible, and can be designed for weight, volume, and cost reduction.

Another advantage of the present invention is that the power semiconductor switches connected to the capacitor can be placed within the hollow center of the capacitor, and be configured such that current in the capacitor is more equally distributed. The advantage is that the center area is an efficient location to place power semiconductor switches and will increase the power density of the inverter.

Another advantage of the present invention is that the power semiconductor switches can be arranged in a such a way that a pair of 4 corner bus plates can be configured with 3 semiconductor switches and a DC input as shown in FIG. 8 to reduce cost, volume, and weight.

Another advantage of the present invention as embodied in FIG. 8 is that it can be manufactured using simple techniques, resulting in low cost and good repeatability.

### BRIEF DESCRIPTION OF THE SEVERAL VIEWS OF THE DRAWING

FIG. 1 is a top view of the annular capacitor with a single power conversion component configured as taught in the patent.

FIG. 1B is a side view cross-section of the capacitor in FIG. 1

FIG. 2 is a top view of the annular capacitor with a single power conversion component configured for low temperature rise.

FIG. 3 is a top view of the annular capacitor with three power conversion components configured for low inductance and low capacitor temperature rise.

FIG. 4 is a cross-sectional side view of the annular capacitor showing a portion of the assembly and detailing the connections of the semiconductor switching die mounted in the center hole and attached to a cold plate. [integrated capacitor/switch assembly]

FIG. 5 is a cross-sectional side view of the annular capacitor showing a portion of the assembly and detailing the connections of the semiconductor switching die mounted in the center hole and electrically insulated from the cold plate. [integrated capacitor/switch assembly]

FIG. 6 is a top view of the annular capacitor with three power conversion components equally spaced around the outside edge for low inductance and low temperature rise.

FIG. 7 is a top view of the annular capacitor with a space effective arrangement of three power conversion components and the DC input.

FIG. 8 is a top view of the annular capacitor of FIG. 7 further refined with the offset bus plates offering convenient connections between the capacitor, the three power conversion components and the DC input. This figure includes an enlarged, angled partial view for detail clarification.

FIG. 9 is a top view of the annular capacitor with three power conversion components equally spaced around the outside edge for low inductance and low temperature rise with the DC input located at the center hole.

### DETAILED DESCRIPTION OF THE INVENTION

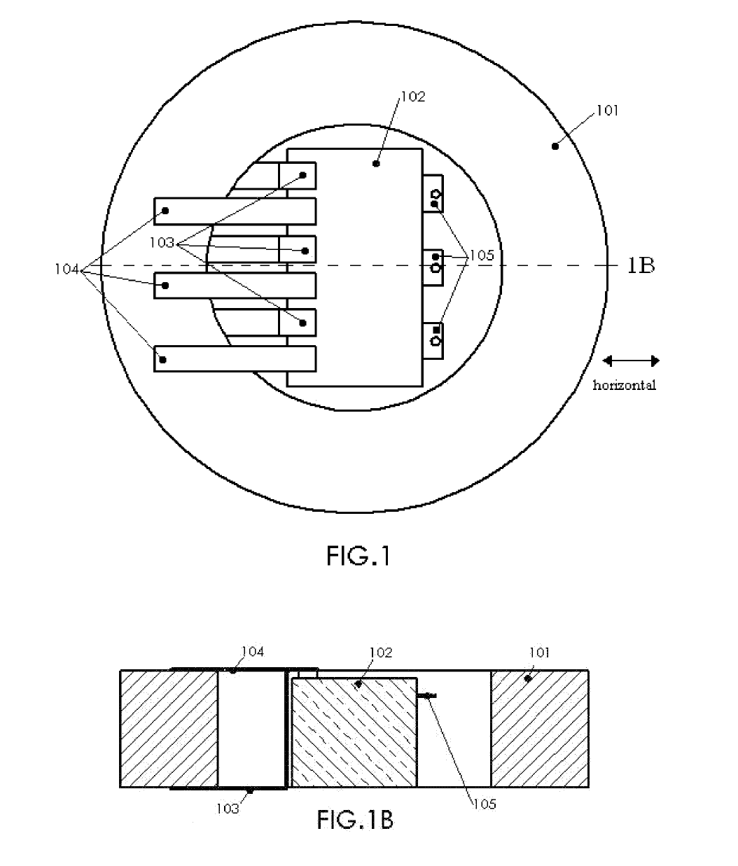

A metallized film polymeric annular capacitor with a single power conversion component is shown in FIG. 1. The annular capacitor body 101 has a variable center hole radius that can be made to fit a power conversion component 102 to exact specifications with the necessary space for the upper terminals 104, lower terminals 103, and output terminals 105 of the component. In FIG. 1 the terminals are positioned for the shortest path possible with a typical, commercially available power conversion component. The outer radius and thickness of the annular capacitor can then be selected to achieve the desired capacitance for the power conversion application. The thickness of the annular capacitor is addressed in FIG. 1B. The depth of the annular capacitor 101 is made to match the height of the power conversion component 102 so that the terminals 103 and 104 can maintain the shortest distance for connection to the capacitor, and thereby the lowest connection inductance possible for this configuration. It is to be understood that the illustrated power conversion component is but one of many existing or future commercially available power conversion components that could be similarly accommodated within the capacitor center hole.

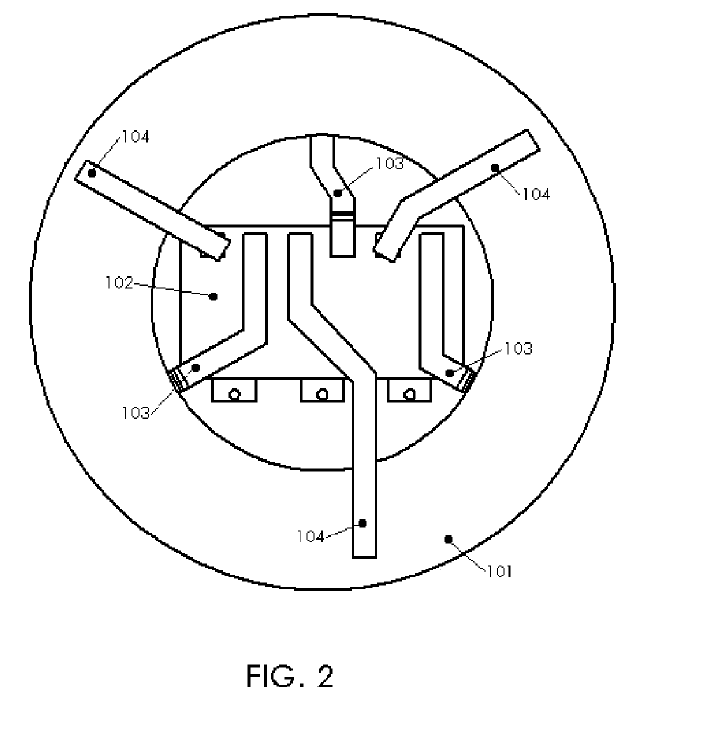

The annular capacitor in FIG. 2 shows a single power conversion component 102 again in the center hole of the capacitor body 101. The upper terminals 104 and lower terminals 103 in this example are distributed equally spaced around the ring. This arrangement does not provide the shortest connection path, but will better distribute the capacitor current which will reduce the annular capacitor temperature rise. Again the depth of the annular capacitor would match the height of the power conversion component, as was shown in FIG. 1B. The thickness and inner radius of the capacitor being thus determined, the outer radius would vary to produce the desired capacitance. In practice, a compromise decision must be made concerning terminal placement as to which is more important to an application regarding temperature rise vs. low connection inductance. It should be noted that variation of capacitor width/shape may be implemented while still meeting the intent of more uniform current density within the capacitor.

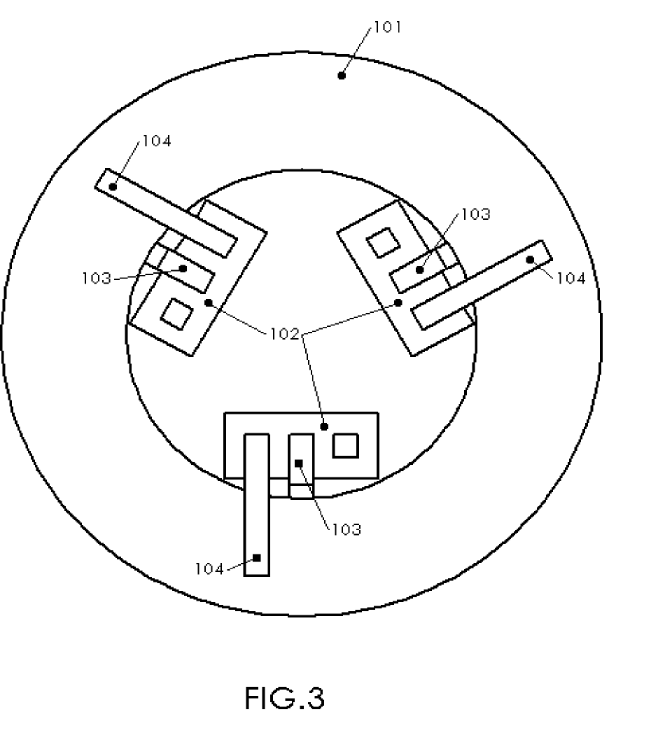

Depending on the application it may be advantageous to use more than one power conversion component. An example of a three point connection method for a three-phase inverter minimizing both capacitor temperature rise and connection inductance is shown in FIG. 3. The power conversion components 102 are located within the inner hole of the annular capacitor body 101. The radius of the inner hole is determined by the size of the components used. In this embodiment the components are positioned to better distribute the capacitor current. This will minimize the temperature rise in the annular capacitor. Matching the depth of the ring to the height of the components, as was shown in FIG. 1B, will also take advantage of using the shortest path possible for the connections of the terminals 104 and 103 and thereby also result in the lowest connection inductance. It is to be understood that the illustrated arrangement of components is but one example of any number or size of the commercially available power conversion components that could be similarly accommodated.

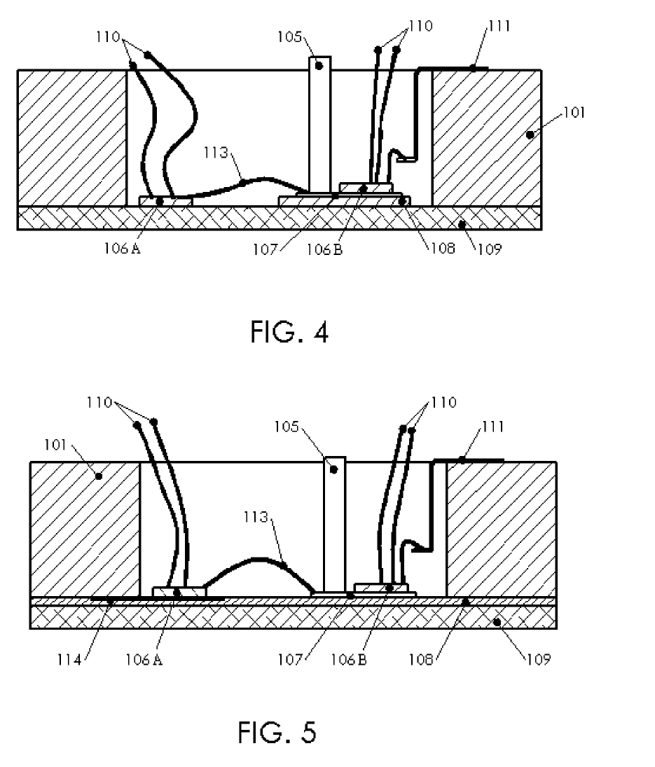

FIG. 4 is a cross section view that illustrates an embodiment where the capacitor and semiconductor switches are integrated into a single unit to achieve better space efficiency than can be had using separate commercially available packaged power conversion components. The semiconductor switching die 106A and 106B are representative in part or in whole of what would normally be contained within a commercially packaged semiconductor device [such as is simplistically illustrated in FIG. 3, reference 102]. The components are located in the center hole of the annular capacitor 101. In this embodiment one semiconductor switching die 106A is directly connected to the cold plate 109, which is in turn directly connected to the bottom face of the capacitor. This becomes, in effect, the lower terminal referred to in previous drawings. With the first semiconductor switching die 106A connected to the cold plate it is necessary for the second semiconductor switching die 106B to be electrically isolated from the electrically active cold plate. This is accomplished with a layer of thermally conductive electrically insulating material 108. This semiconductor switching die 106B is connected 111 to the upper face of the capacitor and is effectively the upper terminal referred to in previous drawings. Semiconductor switching die 106B is connected to the output terminal 105 by a small conductive copper plate 107. The switch semiconductor drive and return bond wires 110, and multiple emitter bond wires 113 are shown to make the drawing more clear and credible. It is to be understood that this illustration shows only a portion of the power conversion components that would be well known to those skilled in the art. It is to be further understood that any number of components may be crafted and used within the ring as shown and described in FIG. 4.

FIG. 5 is a cross section view that illustrates another embodiment where the capacitor and semiconductor switches are integrated into a single unit to achieve better space efficiency than can be had using separate commercially available packaged power conversion components. The semiconductor switching die 106A and 106B are representative in part or in whole of what would normally be contained within a commercially packaged semiconductor device [such as is simplistically illustrated in FIG. 3, reference 102]. The components are located in the center hole of the annular capacitor 101. In this embodiment the thermally conductive electrically insulating layer 108 covers the entire surface between the capacitor 101 and the cold plate 109. Semiconductor switching die 106A, connected to the capacitor by a small conductive plate 114, is effectively the lower terminal referred to in previous drawings. As in FIG. 4, semiconductor switching die 106B is connected 111 to the upper face of the capacitor and is effectively the upper terminal referred to in previous drawings. Semiconductor switching die 106B is connected to the output terminal 105 by a small conductive copper plate 107. The switch semiconductor drive and return bond wires 110, and multiple emitter bond wires 113 are shown to make the drawing more clear and credible. It is to be understood that this illustration shows only a portion of the power conversion components that would be well known to those skilled in the art. It is to be further understood that any number of components may be crafted and used within the ring as shown and described in FIG. 5.

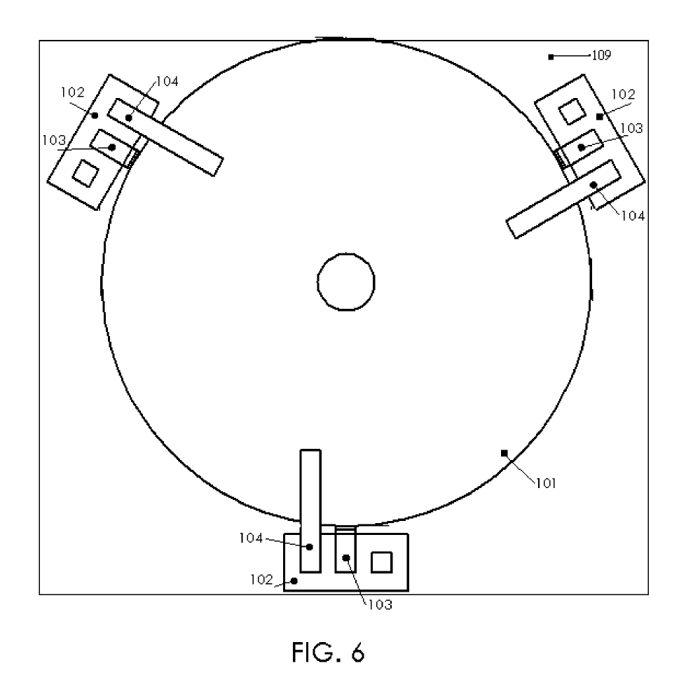

A different embodiment where the power conversion components 102 are distributed around the outside circumference of the capacitor 101 on a cold plate 109 is shown in FIG. 6. In the illustrated three-phase inverter example the resulting capacitor current distribution will be spaced symmetrically around the capacitor outer circumference. This would produce the same capacitance value as the embodiments shown in FIG. 1-5 with a smaller ring diameter. Matching the depth of the ring to the height of the components, as was exemplified by FIG. 1B, will also take advantage of the shortest connection length of the terminals 104 and 103 resulting in low inductance. Note that the connection length of the terminals 103 and 104 will be slightly shorter in this embodiment than for that illustrated in FIG. 3. It is to be understood that the illustrated arrangement of components is but one example of any number or size of the commercially available power conversion components that could be similarly located around the capacitor to achieve more uniform current density within the capacitor for any power conversion application.

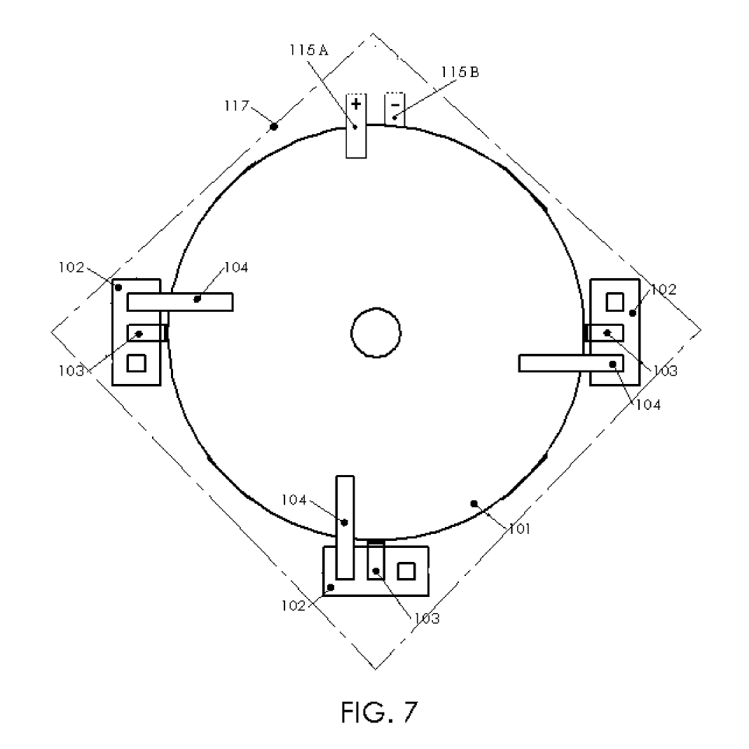

The enclosure line 117 of FIG. 7 suggests an arrangement of switching semiconductors 102 around the annular capacitor 101. This allows more space efficient usage of a power conversion enclosure volume. In the illustrated case the outer perimeter of the capacitor is divided equally between the power conversion components and the DC Input. DC Input terminals 115A and 115B are located in one quadrant, and the three power conversion components 102 are located in the other three quadrants. The switching components 102 are not as evenly distributed around the entire capacitor 101 as was shown in FIG. 6, but the resulting capacitor current distribution is still much more uniform than shown in FIG. 1, and the trade off for the significant space efficiency gains is minimal. Again the depth of the ring matches the height of the components so that the upper terminals 104 and lower terminals 103 can obtain the advantage of short connection length [low inductance]. While the drawing shows a three-phase inverter and single input terminal pair, it is to be understood that any number of components or DC input terminal pairs may be similarly distributed to reap the benefits of the stated advantages within any given space efficient arrangement. Inner and outer radii, and depth of the annular capacitor will be determined by the components used and the requirements of the application as described above.

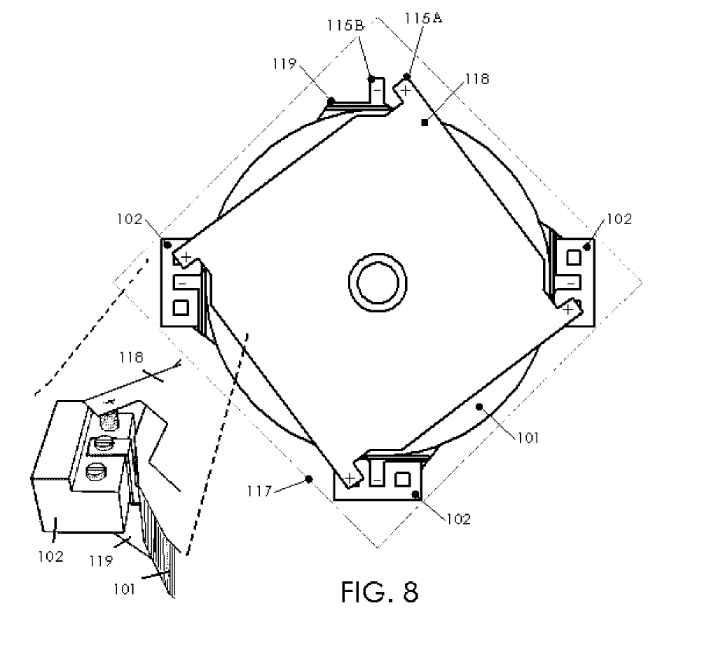

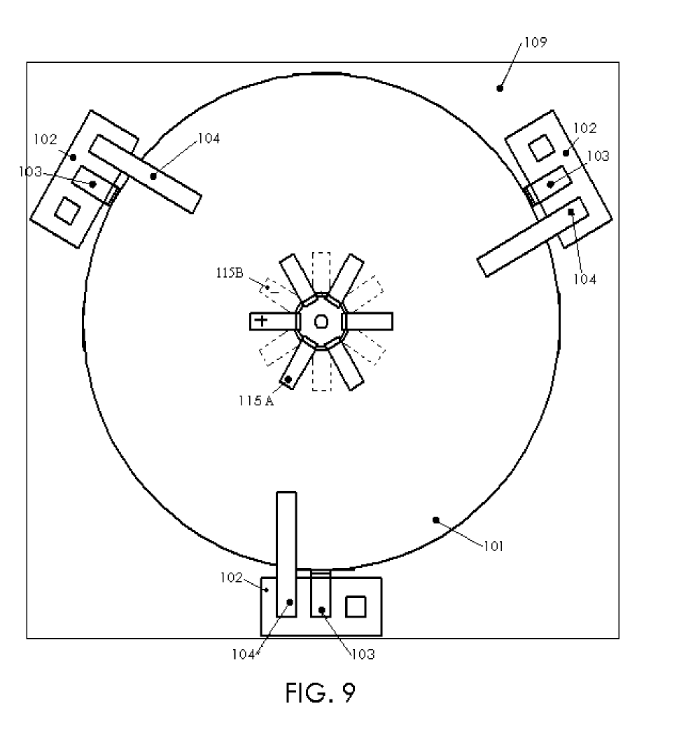

FIG. 8 further refines the space efficient arrangement of components as described in FIG. 7. The enclosure line 117 defines the space. The capacitor 101 is sandwiched between two bus plates. The top bus plate 118 provides a convenient way to connect the positive DC Input 115A and the positive terminals of the power conversion components. The bottom bus plate 119 provides a convenient way to connect the negative DC Input 115B and the negative terminals of the power conversion components. Inner and outer radii, and depth of the annular capacitor will be determined by the components used and the requirements of the application as described above. Included in FIG. 8 is an enlarged, angled view detailing the connections between a power conversion component 102, the capacitor 101, and the top and bottom bus plates 118 and 119.

As illustrated in FIG. 9 the DC Input to the assembly can be attached via the center hole of the capacitor 101, with the connection points evenly distributed. The positive DC Input 115A is attached to one side of the capacitor and the negative DC Input 115B to the other side of the capacitor. The power conversion components 102 are distributed around the perimeter to take advantage of the benefits as described for FIG. 6. To further increase the capacitor low temperature rise advantage the negative DC Input 115B to the assembly can be connected using a cold plate 109 as an input connection and thusly distributing the current equally across the face of the capacitor. The positive DC Input 115A would be connected as above. Ultimately the DC Input connections could be a disc shape attached to the entire inner circumference of the capacitor. While the drawing shows a three-phase inverter, it is to be understood that any number of power conversion components may be similarly distributed around a centrally located DC Input to achieve minimum overall temperature rise in the capacitor. Inner and outer radii, and depth of the annular capacitor will be determined by the components used and the requirements of the application as described above.

While only certain features of the invention have been illustrated and described herein, many modifications and changes will occur to those skilled in the art. It is, therefore, to be understood that the appended claims are intended to cover all such modifications and changes as fall within the true spirit of the invention.

What is claimed is:

1. An electrical assembly comprised of a wound film capacitor having the form of an annular ring with an outer diameter that is substantially greater than the thickness of the ring, with electrically conductive contacts located on opposing end faces of said capacitor, with an inner diameter selected to accommodate one or more electrical power control components, where said electrical power control components are located within the inner diameter of said capacitor, and where said electrical power control components are electrically connected with said contacts on said capacitor.

2. An electrical assembly as in claim 1 where the thickness of said capacitor is selected to provide the shortest connection path possible between the electrical contacts located on opposing end faces of said capacitor and one or more said electrical power control components located within the inner diameter of said capacitor, to minimize the total inductance of the electrical circuit formed thereby.

3. An electrical assembly as in claim 2 where the electrical connection between electrical contacts of said capacitor and one or more said electrical power control components is accomplished using a method selected from the list including but not limited to a printed circuit board or an electrically and thermally conductive cold plate.

4. An electrical assembly as in claim 2 where the connection points from each said electrical power control component to the electrical contacts on said capacitor are spaced at regular intervals around the inner circumference of said capacitor to reduce the temperature rise caused by current passing through said capacitor.

5. An electrical assembly as in claim 2 where one or more thermally and electrically conductive plates provide an electrical and thermal connection to one or both end faces of the said capacitor, and where the said electrical power control components are suitably located to maintain the full functionality of the said assembly.

6. An electrical assembly as in claim 2 where an electrically insulating and thermally conductive layer is positioned between one or more thermally and electrically conductive plates to provide electrical insulation between one or both end faces of said capacitor and said thermally and electrically conductive plates, and where said electrical power control components are suitably located to maintain the full functionality of the said assembly.

7. An electrical assembly as in claim 2 where more than one electrical contacts on each end face of said capacitor are equally distributed around the inner circumference of said capacitor to reduce the temperature rise of said capacitor.

8. An electrical assembly as in claim 2 where one or more electrically and thermally conductive endplates are connected to the opposing end faces of said capacitor, where said endplates are substantially larger than the end faces of said capacitor, where said endplates are positioned to be offset from each other, where the said plates have tabs or flanges that extend beyond the outer diameter of the outer circumference of said capacitor for the purpose of connecting to said electrical power control components, and where said electrical power control components are fastened to said endplates in a manner that maintains full functionality of said assembly.

9. An electrical assembly as in claim 8 where said electrical assembly is designed to control both direct current and alternating current electrical power flows, where the direct current introduced to the assembly is connected to one or more of the said tabs or flanges on the said endplates to optimize the heat dissipation from the combination of AC and DC current in the assembly.

10. An electrical assembly as in claim 9 where said endplates are fastened to one or more thermally conductive cooling plates using an electrically insulating and thermally conductive layer.

11. An electrical assembly as in claim 2 where direct current is introduced to said assembly through an electrical connection located within the inner diameter on a first end face of said capacitor, where direct current is removed from said assembly through an electrical connection located within the inner diameter on the second end face of said capacitor, where the direct current connection points are equally distributed around the inner circumference of said capacitor, and where the direct current contacts are selected from the list including but not limited an array of electrical tabs or a disc shaped continuous electrode.

12. An electrical assembly as in claim 2 where direct current is introduced to or removed from said assembly through an electrical connection formed by an electrically and thermally conductive cold plate placed in contact with one end face of said capacitor, where direct current is removed from or introduced to said assembly through an electrical connection located within the inner diameter on the opposite end face of said capacitor, where the direct current connection points are equally distributed around the inner circumference of said capacitor, and where the direct current contacts are selected from the list including but not limited an array of electrical tabs or a disc shaped continuous electrode.

13. An electrical assembly comprised of a wound film capacitor having the form of an annular ring with an outer diameter that is greater than the thickness of the ring, with electrically conductive contacts located on opposing end faces of said capacitor, where one or more electrical power control components are distributed around the outside circumference of said capacitor ring, and where said electrical power control components are electrically connected with the said contacts on said capacitor.

14. An electrical assembly as in claim 13 where the thickness of said capacitor is selected to provide the shortest connection path possible between the electrical contacts located on opposing end faces of the capacitor and one or more said electrical power control components located around the outer circumference of said capacitor, to minimize the total inductance of the electrical circuit formed thereby.

15. An electrical assembly as in claim 14 where the electrical connection between electrical contacts of said capacitor and one or more said electrical power control components is accomplished using a method selected from the list including but not limited to a printed circuit board or an electrically and thermally conductive cold plate.

16. An electrical assembly as in claim 14 where the connection points from each said electrical power control component to the electrical contacts on said capacitor are spaced at regular intervals around the outer circumference of said capacitor to reduce the temperature rise caused by current passing through said capacitor.

17. An electrical assembly as in claim 14 where one or more thermally and electrically conductive plates provide an electrical and thermal connection to one or both end faces of said capacitor, and where said electrical power control components are suitably located to maintain the full functionality of said assembly.

18. An electrical assembly as in claim 14 where an electrically insulating and thermally conductive layer is positioned between one or more thermally and electrically conductive plates to provide electrical insulation between one or both end faces of said capacitor and said thermally and electrically conductive plates, and where said electrical power control components are suitably located to maintain the full functionality of said assembly.

19. An electrical assembly as in claim 14 where more than one electrical contacts on each end face of said capacitor are equally distributed around the outer circumference of said capacitor to reduce the temperature rise of said capacitor.

20. An electrical assembly as in claim 14 where one or more electrically and thermally conductive endplates are connected to the opposing end faces of said capacitor, where said endplates are substantially larger than the end faces of said capacitor, where said endplates are positioned to be offset from each other, where said plates have tabs or flanges that extend beyond the outer diameter of the outer circumference of said capacitor for the purpose of connecting to said electrical power control components, and where said electrical power control components are fastened to said endplates in a manner that maintains full functionality of said assembly.

21. An electrical assembly as in claim 20 where said electrical assembly is designed to control both direct current and alternating current electrical power flows, where the direct current introduced to said assembly is connected to one or more of said tabs or flanges on said endplates to optimize the heat dissipation from the combination of alternating current and direct current in said assembly.

22. An electrical assembly as in claim 21 where said endplates are fastened to one or more thermally conductive cooling plates using an electrically insulating and thermally conductive layer.

23. An electrical assembly as in claim 14 where direct current is introduced to said assembly through an electrical connection located within the inner diameter on a first end face of said capacitor, where direct current is removed from said assembly through an electrical connection located within the inner diameter on the second end face of the said capacitor, where the direct current connection points are equally distributed around the inner circumference of said capacitor, and where the direct current contacts are selected from the list including but not limited an array of electrical tabs or a disc shaped continuous electrode.

24. An electrical assembly as in claim 14 where direct current is introduced to or removed from said assembly through an electrical connection formed by an electrically and thermally conductive cold plate placed in contact with one end face of said capacitor, where direct current is removed from or introduced to said assembly through an electrical connection located within the inner diameter on the opposite end face of said capacitor, where the direct current connection points are equally distributed around the inner circumference of said capacitor, and where the direct current contacts are selected from the list including but not limited an array of electrical tabs or a disc shaped continuous electrode.
